(19) United States
(12) Patent Application Publication
(10) Pub. No.: US 2014/0159083 A1
(43) Pub. Date: Jun. 12, 2014

(54) SEMICONDUCTOR LIGHT EMITTING DEVICE AND FABRICATION METHOD THEREOF

(71) Applicants: Jae Ho Han, (US); Myeong Ha Kim, (US); Jae Yoon Kim, (US)

(72) Inventors: Jae Ho Han, (US); Myeong Ha Kim, (US); Jae Yoon Kim, (US)

(73) Assignee: SAMSUNG ELECTRONICS CO., LTD., Suwon-si (KR)

(21) Appl. No.: 13/708,567

(22) Filed: Dec. 7, 2012

(51) Int. Cl. H01L 33/36; H01L 33/42; H01L 33/40

(52) U.S. Cl. CPC H01L 33/36; H01L 33/405; H01L 33/42
USPC 257/98; 257/99

(57) ABSTRACT

A semiconductor light emitting device includes a first conductivity-type semiconductor layer, an active layer, a second conductivity-type semiconductor layer, an insulating region formed along the outer edges of an upper surface of the second conductivity-type semiconductor layer, and an ohmic-electrode layer disposed on the second conductivity-type semiconductor layer.

### CROSS-REFERENCE TO RELATED APPLICATIONS

This application claims the priority to Korean Patent Application No. 10-2011-0131966 filed on Dec. 9, 2011, in the Korean Intellectual Property Office, the disclosure of which is incorporated herein by reference.

### TECHNICAL FIELD

The present application relates to a semiconductor light emitting device and a fabrication method thereof.

### BACKGROUND

A light emitting diode (LED), a type of semiconductor light emitting device using a compound semiconductor material such as GaAs, AlGaAs, AlGaInP, AlGaInN, or the like, is commonly used as a light source to obtain light within a particular wavelength band.

An LED is a semiconductor device that emits light of various colors according to the recombination of electrons and holes at p-n junctions when an electrical current is applied thereto. The LED is environmentally-friendly, has a fast response time in the range of a few nano-seconds to thus be effective for a video signal stream, and is available for impulsive driving. In addition, an LED has a color gamut of 100% or higher, can easily change the luminance of emitted light, a color temperature, or the like, by adjusting the quantity of light emitted by red, green, and blue LED chips. Due to such advantages, the LED has been widely used as a light emitting element for various light emitting devices.

In particular, recently, an LED as a light source of light within a blue or green wavelength band has been applied to a variety of products such as a mobile device keypad, a backlight unit, a traffic light, an airstrip landing light, an illuminated sign, a general lighting system, and the like.

Methods for implementing a high luminance and high efficiency LED include, for example, a method of lowering a non-radiative recombination probability, a method of lowering resistance of a semiconductor layer, a method of lowering contact resistance between an electrode and a semiconductor, a method of lowering a loss of light due to total internal reflection or light absorption within a device, a method of improving an electrode disposition or a design of an LED, and the like.

A need still exists to provide a semiconductor light emitting device having increased light output.

### SUMMARY

An aspect of the present application provides a semiconductor light emitting device from which a quantity of light emitted to the outside is increased, and a fabrication method thereof. However, an object of the present application is not limited thereto and any objects and effects that can be recognized from the technical solutions and examples described hereinafter may be included therein, even if not clarified.

According to an aspect of the present application, there is provided a semiconductor light emitting device. The device includes a first conductivity-type semiconductor layer; an active layer disposed on the first conductivity-type semiconductor layer; and a second conductivity-type semiconductor layer disposed on the active layer. An insulating region is disposed along the outer edges of an upper surface of the second conductivity-type semiconductor layer An ohmic-electrode layer is disposed on the second conductivity-type semiconductor layer. A first electrode is disposed on a portion of the first conductivity-type semiconductor layer and a second electrode disposed on a portion of the ohmic-electrode layer.

The insulating region may be disposed to have an annular shape on the outer edges of the upper surface of the second conductivity-type semiconductor layer.

A distance from the outermost edge of the second conductivity-type semiconductor layer to an inner circumferential surface of the insulating region may range from 5 μm to 45 μm.

A mesa etched region may be disposed by removing portions of the active layer and the second conductivity-type semiconductor layer such that a portion of the first conductivity-type semiconductor layer is exposed, and the first electrode may be formed in the mesa etched region.

The insulating region may be divided into a plurality of separated insulating regions, and one of the plurality of separated insulating regions may be disposed to surround the mesa etched region when viewed from above.

The insulating region may be disposed to surround the ohmic-electrode layer and the first and second electrodes when viewed from above.

The semiconductor light emitting device may further include a current spreading region made of an electrical insulation material and disposed in a position corresponding to the second electrode below the second electrode.

The current spreading region may be disposed to have the same shape as that of the second electrode.

The current spreading region may be made of the same material as that of the insulating region.

The insulating region may have an inner circumferential surface having depressions and protrusions disposed therein.

The ohmic-electrode layer may be disposed to cover at least a portion of the insulating region.

The ohmic-electrode layer may be made of a light-transmissive material.

The ohmic-electrode layer may be made of a light-reflective material. According to another aspect of the present application, there is provided a method for fabricating a semiconductor light emitting device. The method includes sequentially forming a first conductivity-type semiconductor layer, an active layer, and a second conductivity-type semiconductor layer on a substrate A insulating region is disposed along outer edges of an upper surface of the second conductivity-type semiconductor layer. An ohmic-electrode layer is disposed on the second conductivity-type semiconductor layer. A first electrode is disposed on a portion of the first conductivity-type semiconductor layer; and a second electrode is disposed on a portion of the ohmic-electrode layer.

The disposing of the insulating region may be performed such that the insulating region has an annular shape.

A distance from the outermost edge of the second conductivity-type semiconductor layer to an inner circumferential surface of the insulating region may range from 5 μm to 45 μm.

Two or more insulating regions may be provided.

The method may further include the step of removing portions of the active layer and the second conductivity-type semiconductor layer such that a portion of the first conductivity-type semiconductor layer is exposed, to form a mesa etched region, before the disposing of the insulating region The first electrode is disposed in the mesa etched region.

One of the two or more insulating regions may be disposed to surround the mesa etched region when viewed from above.

The method may further include the step of disposing a current spreading region made of an electrical insulation material in a position corresponding to the second electrode, before the step of disposing the second electrode.

The current spreading region may be disposed to have the same shape as that of the second electrode.

The current spreading region may be made of the same material as that of the insulating region.

The current spreading region and the insulating region may be simultaneously disposed.

Another aspect of the present application includes providing a semiconductor light emitting device. The device includes a first conductivity-type semiconductor layer; an active layer disposed on the first conductivity-type semiconductor layer; and a second conductivity-type semiconductor layer disposed on the active layer. An insulating region is formed along outer edges of an upper surface of the second conductivity-type semiconductor layer. An ohmic-electrode layer is disposed on the second conductivity-type semiconductor layer. A first electrode is disposed on a portion of the first conductivity-type semiconductor layer. A trench extends through the second conductivity-type semiconductor layer, the active layer and a portion of the first conductivity-type semiconductor layer.

Another aspect of the present application includes providing a semiconductor light emitting device. The device includes a first conductivity-type semiconductor layer; an active layer disposed on the first conductivity-type semiconductor layer; a second conductivity-type semiconductor layer disposed on the active layer. An insulating region is disposed along outer edges of an upper surface of the second conductivity-type semiconductor layer. An ohmic-electrode layer is disposed on the second conductivity-type semiconductor layer. A conductive substrate is disposed on the ohmic-electrode layer. A first electrode is disposed on a portion of the first conductivity-type semiconductor layer, and a second electrode disposed on a portion of the ohmic-electrode layer.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIGS. 1 and 2 are a cross-sectional view and a plan view schematically showing a semiconductor light emitting device according to an example of the present application;

FIG. 3 is a graph of a change in a quantity of light of the semiconductor light emitting device over a size of an insulating region;

FIGS. 4 and 5 are cross-sectional views schematically showing a semiconductor light emitting device according to a modification of FIG. 1;

FIG. 6 is a graph showing a comparison of optical power between devices according to an example of the present application and a comparative example;

FIG. 7 is a cross-sectional view schematically showing a nitride semiconductor light emitting device according to another example of the present application; and

FIGS. 8 through 12 are cross-sectional views schematically showing a sequential process of a method for fabricating a semiconductor light emitting device according to an example of the present application.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

Examples of the present application will now be described in detail with reference to the accompanying drawings.

The application may, however, be embodied in many different forms and should not be construed as being limited to the examples set forth herein. Rather, these examples are provided so that this disclosure will be thorough and complete, and will fully convey the scope of the application to those skilled in the art. In the drawings, the shapes and dimensions of elements may be exaggerated for clarity, and the same reference numerals will be used throughout to designate the same or like components.

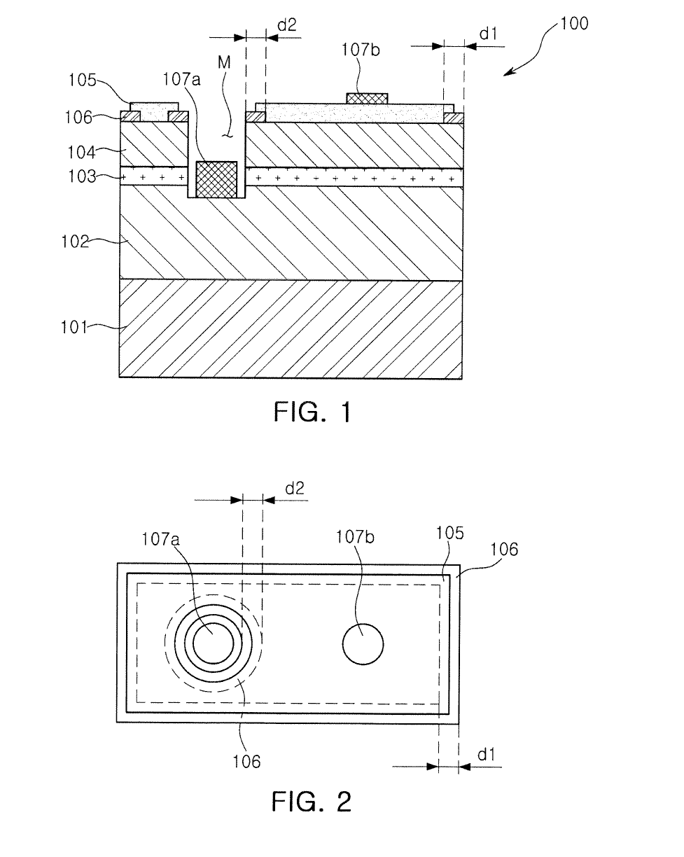

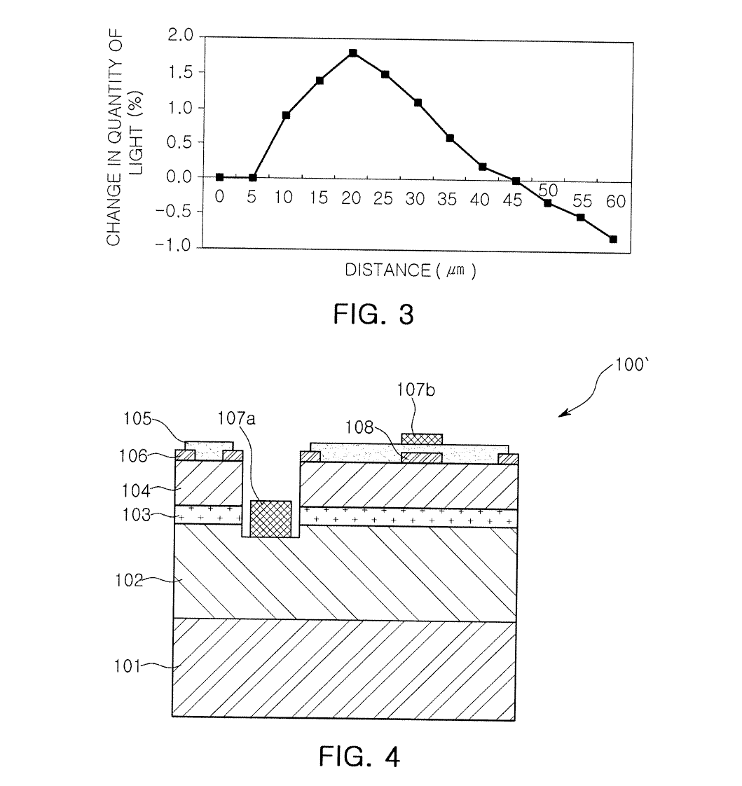

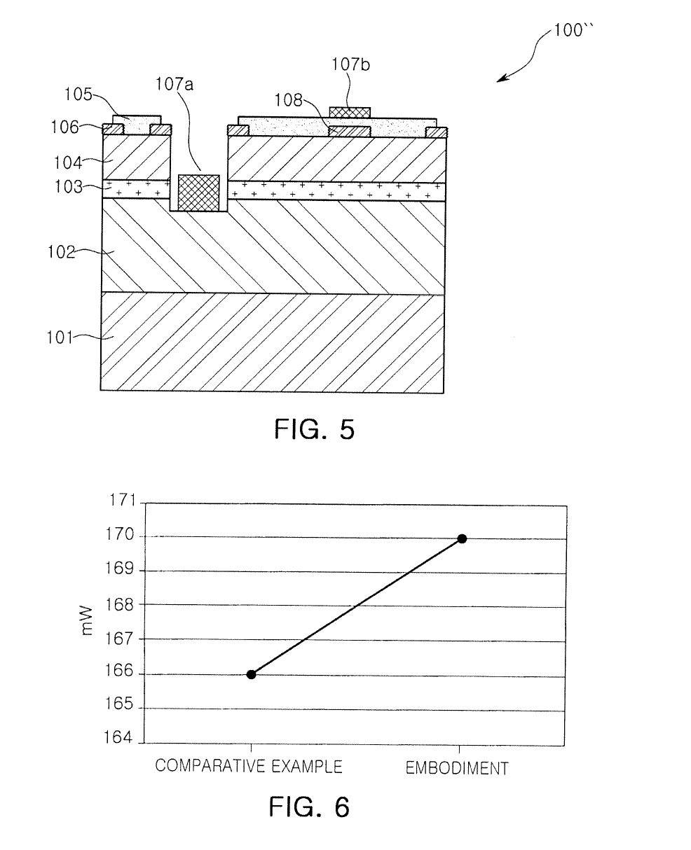

FIGS. 1 and 2 are a cross-sectional view and a plan view schematically showing a semiconductor light emitting device according to an example of the present application. FIG. 3 is a graph of a change in a quantity of light of the semiconductor light emitting device over a size of an insulating region. FIGS. 4 and 5 are cross-sectional views schematically showing a semiconductor light emitting device according to a modification of FIG. 1.

First, with reference to FIGS. 1 and 2, a semiconductor light emitting device 100 according to the present example may include a substrate 101, a first conductivity-type semiconductor layer 102, an active layer 103, a second conductivity-type semiconductor layer 104, an ohmic-electrode layer 105, and an insulating region 106. First and second electrodes 107a and 107b are disposed on upper surfaces of the first conductivity-type semiconductor layer 102 and the ohmic-electrode layer 105, respectively. Here, terms such as ‘upper portion’, ‘upper surface’, ‘lower portion’, ‘lower surface’, ‘lateral surface’, or the like, are used based on the directionality of the drawings, which may be changed according to the direction in which the device is actually disposed.

The substrate 101 is a semiconductor growth substrate. The substrate 101 is made of an insulating, conductive, or semiconductive material, such as sapphire, Si, SiC, MgAl₂O₄, MgO, LiAlO₂, LiGaO₂, GaN, or the like. In this case, sapphire having electrical insulation characteristics may most preferably be used. Sapphire is a crystal having Hexa-Rhombo R3c symmetry, of which lattice constants in c-axis and a-axis directions are 13.001 Å and 4.758 Å, respectively. A sapphire crystal has a C (0001) plane, an A (1120) plane, an R (1102) plane, and the like. In this case, a nitride thin film can be relatively easily disposed on the C plane of the sapphire crystal, and because sapphire crystal is stable at high temperatures, it is commonly used as a material for a nitride growth substrate. A silicon (Si) substrate may be appropriately used as the substrate 101, and mass-production can be facilitated by using the silicon (Si) substrate which may have a large diameter and be relatively low in price. When the silicon (Si) substrate is used, a nucleation layer made of a material such as AlₓGa₁₋ₓN (0<x≦1) may be disposed on the substrate 101 and a nitride semiconductor having a desired structure may be grown on the nucleation layer.

The first and second conductivity-type semiconductor layers 102 and 104 may be semiconductor layers doped with n-type and p-type impurities, respectively, but the present application is not limited thereto. Conversely, the first and second conductivity-type semiconductor layers 102 and 104 may be p-type and n-type semiconductor layers, respectively. Also, the first and second conductivity-type semiconductor layers 102 and 104 may be made of a nitride semiconductor, e.g., a material having a composition of AlₓIn_{y}Ga_{1-x-y}N (0≦x≦1, 0≦y≦1, 0≦x+y≦1). Each of the semiconductor layers 102 and 104 may be configured as a single layer, or multiple layers each having different characteristics such as a doping concentration, a composition, or the like. The n-type and p-type semiconductor layers 102 and 104 may be made of an AlInGaP or AlInGaAs semiconductor, besides the nitride semiconductor.

The active layer 103, disposed between the first and second conductivity-type semiconductor layers 102 and 104, emits light having a certain energy level according to the recombination of electrons and holes and may have a multi-quantum well (MQW) structure in which quantum well layers and quantum barrier layers are alternately laminated. In the case of the nitride semiconductor, the quantum well layers may be made of InGaN (the content of In and Ga may be variable) and the quantum barrier layers may include regions made of GaN, InGaN (the content of In and Ga may be variable and the content of In may be less than that of the quantum well layers), and AlInGaN (the content of Al, In, and Ga may be variable).

The first and second conductivity-type semiconductor layers 102 and 104 and the active layer 103 constituting the light emitting structure may be grown by a conventional process, such as metal organic chemical vapor deposition (MOCVD), hydride vapor phase epitaxy (HVPE), molecular beam epitaxy (MBE), or the like. Although not shown, in order to lessen stress acting on the first conductivity-type semiconductor layer 102 to thus enhance crystallinity, a buffer layer may be disposed on the substrate 101 before the first conductivity-type semiconductor layer 102 is formed. Further, although not shown, an electron blocking layer having a relatively high energy band gap may be interposed between the active layer 103 and the second conductivity-type semiconductor layer 104 to prevent electrons from overflowing upon passing through the active layer 103.

The ohmic-electrode layer 105 may be made of a material that exhibits electrical ohmic-characteristics with the second conductivity-type semiconductor layer 104. The ohmic-electrode layer 105 may be formed of a transparent conductive oxide such as ITO, CIO, ZnO, or the like. The ohmic-electrode layer 105 has a high level of light transmittance and relatively excellent ohmic-contact performance among materials used for a transparent electrode. Alternatively, the ohmic-electrode layer 105 may be made of a light-reflective material, e.g., a highly reflective metal, and in this case, the device 100 may have a so-called flip-chip structure in which the first and second electrodes 107a and 107b are disposed toward a mounting region, e.g., a lead frame, or the like, of a package.

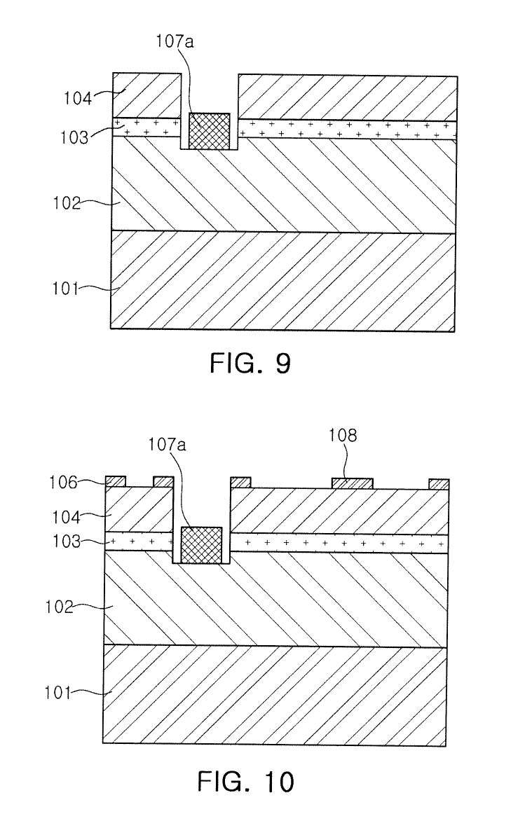

The first and second electrodes 107a and 107b may be made of a conventional material having electrical conductivity. For example, the first and second electrodes 107a and 107b may be formed by depositing, sputtering, or the like, one or more of silver (Ag), aluminum (Al), nickel (Ni), chromium (Cr), and the like. In the structure illustrated in FIG. 1, the first electrode 107a is formed in a mesa etched region M and the second electrode 107b is disposed on an upper surface of the ohmic-electrode layer 105. However, such an electrode (107a, 107b) formation scheme is merely an example, and electrodes may be formed in various positions on the light emitting structure including the first conductivity-type semiconductor layer 102, the active layer 103, and the second conductivity-type semiconductor layer 104 as shown in the example of FIG. 7.

In the present example, the ohmic-electrode layer 105 is not disposed on the entire surface of the second conductivity-type semiconductor layer 104. Specifically, the ohmic-electrode layer 105 is not disposed on outer edges of the upper surface of the second conductivity-type semiconductor 104. Here, in order to prevent the ohmic-electrode layer 105 from being in contact with the outer edges of the upper surface of the second conductivity-type semiconductor layer 104, an insulating region 106 is formed along the outer edges of the upper surface of the second conductivity-type semiconductor layer 104. In this case, as shown in FIG. 1, the ohmic-electrode layer 105 may be formed to cover at least a portion of the insulating region 106. The insulating region 106 is made of a material having electrical insulation such as a silicon oxide, a silicon nitride, an aluminum oxide, or the like, and also may be made of any other materials having electrical insulation characteristics.

When a portion of the light emitting structure formed by growing semiconductor layers is removed through etching, or the like, crystal of the remaining regions may be damaged to increase non-radiative recombination in the remaining regions. A portion of the light emitting structure can be removed through etching, or the like. For example, the mesa etched region (M) is formed by removing portions of the active layer 103 and the second conductivity-type semiconductor layer 104 such that a portion of the first conductivity-type semiconductor layer 102 is exposed to form the first electrode 107a, and dicing the light emitting structure grown by wafer into chip units, or the like. Thus, the insulating region 106 is formed along the outer edges of the upper surface of the second conductivity-type semiconductor layer 104 to prevent non-radiative recombination in the outer edge regions of the chip having a low level of crystallinity to thus enhance luminance efficiency.

In this case, as shown in FIG. 2, the insulating region 106 may be formed to have an annular shape along the outer edges of the upper surface of the second conductivity-type semiconductor layer 104. Here, the annular shape may correspond to any structure as long as the interior thereof is hollow in a penetrative manner in one direction, regardless of a shape thereof. Also, the insulating region 106 may be divided into two or more separated regions. Here, one of the two or more insulating regions may be formed to surround the mesa etched region M, while the other may be disposed on the entire outer edges of the chip, i.e., the outermost edges of the upper surface of the second conductivity-type semiconductor layer 104, to surround the ohmic-electrode layer 105 and the first and second electrodes 107a and 107b, when viewed from above.

Meanwhile, although the insulating region 106 serves to reduce non-radiative recombination, if the region in which the ohmic-electrode layer 105 and the second conductivity-type semiconductor layer 104 are in contact is reduced by the presence of the insulating region 106, the overall light emitting region may be reduced. Thus, in consideration of this, the size of the insulating region 106 is required to be appropriately adjusted. FIG. 3 is a graph of a change in a quantity of light of the semiconductor light emitting device over a size of the insulating region. In FIG. 3, a distance (μm) of the insulating region refers to a distance from the outer edges of the upper surface of the second conductivity-type semiconductor layer 104 to an inner circumferential surface of the insulating region 106. The distance (μm) of the insulating region corresponds to d1 and d2 in FIGS. 1 and 2, and here, d1 indicates the width (or distance) of the insulating region 106 disposed on edges which were diced, while d2 indicates the width of the insulating region 106 formed at the periphery of the mesa etched region M.

As shown in FIG. 3, as the size of the insulating region 106 is increased, namely, as the distance from the outer edges of the upper surface of the second conductivity-type semiconductor layer 104 to the inner circumferential surface of the insulating region 106 is increased to be greater than about Sum, the quantity of light is increased. This is considered to be a result of the reduction in the non-radiative recombination in the outer edge region of the chip, as mentioned above. Also, when the distance from the outer edges of the upper surface of the second conductivity-type semiconductor layer 104 to the inner circumferential surface of the insulating region 106 is about 45 μm, the quantity of light may be significantly reduced, and the reason for this may be because an excessive increase in the insulating region 106 may reduce the size of the light emitting region to thus degrade overall luminance efficiency.

Meanwhile, as for the modifications of FIGS. 4 and 5, the semiconductor light emitting devices 100′ and 100″ include the first conductivity-type semiconductor layer 102, the active layer 103, the second conductivity-type semiconductor layer 104, the ohmic-electrode layer 105, and the insulating region 106, like the example of FIG. 1. First, in the case of the example of FIG. 4, the semiconductor light emitting device 100′ further includes a current spreading region 108 formed below the second electrode 107b. The current spreading region 108 may be made of an electrical insulation material and formed in a position corresponding to the second electrode 107b below the second electrode 107b, and induce a current flow in a lateral direction to improve electrostatic resistance characteristics, or the like. The current spreading region 108 may be formed to have the same shape as that of the second electrode 107b, and here, the same shape refers to that the current spreading region 108 and the second electrode 107b have the same shape when viewed from above.

The current spreading region 108 may be made of a material such as a silicon oxide, a silicon nitride, an aluminum oxide, or the like, and in particular, the current spreading region 108 may be made of the same material as that of the insulating region 106. In this case, as described hereinafter, the current spreading region 108 may be simultaneously formed with the insulating region 106 through the same process. Meanwhile, as in the example of FIG. 5, at least one of the insulating region 106 and the current spreading region 108 (both of them in the present example) may have an irregular circumferential surface (i.e., an inner circumferential surface having depressions and protrusions formed therein) to thereby increase the quantity of light emitted to the outside. The modifications of FIGS. 4 and 5 may also be applied to an example described hereinafter.

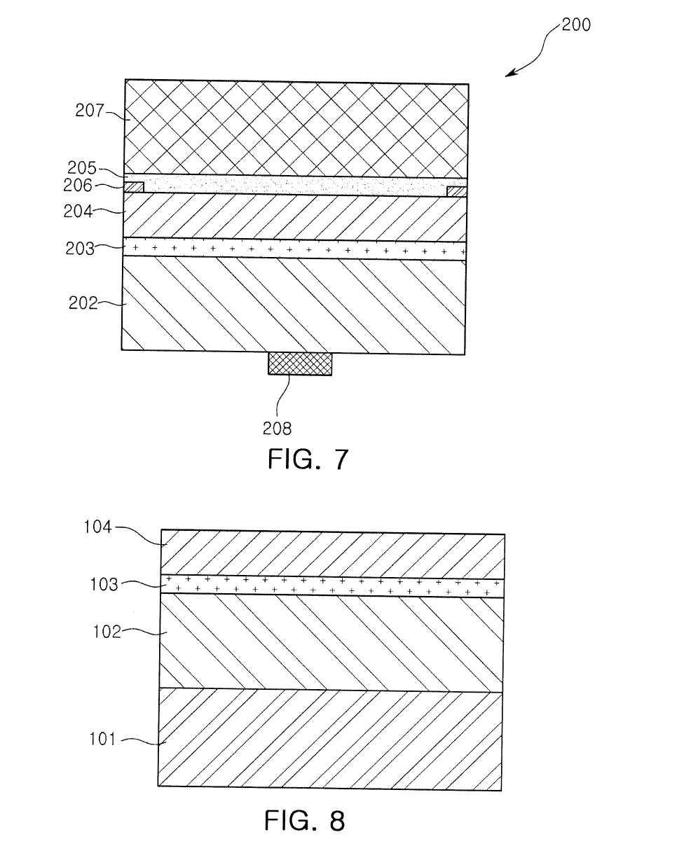

The results obtained by comparing optical powers of the device according to the foregoing example and that of a conventional device will be described. FIG. 6 is a graph showing a comparison of optical power between devices according to an example of the present application and a comparative example. Here, the example employed the structure illustrated in FIG. 4, and the comparative example employed the same structure as that of the FIG. 4 but without the insulating region 106. As shown in the graph of FIG. 6, it can be seen that the formation of the annular insulating region on the edge region of the light emitting structure, namely, the outer edges of the upper surface of the second conductivity-type semiconductor layer, as in the example of the present application, results in obtaining optical power improved by about 2.4%.

FIG. 7 is a cross-sectional view schematically showing a nitride semiconductor light emitting device according to another example of the present application. A nitride semiconductor light emitting device 200 according to the present example includes a light emitting structure and a conductive substrate 207 supporting the light emitting structure. The light emitting structure includes a first conductivity-type semiconductor layer 202, an active layer 203, a second conductivity-type semiconductor layer 204, an ohmic-electrode layer 205, and an insulating region 206. Also, a first electrode 208 is disposed on one surface of the first conductivity-type semiconductor layer 202. Also, in the present example, the insulating region 206 may be formed along the outer edges of the upper surface of the second conductivity-type semiconductor layer 204 to have, in particular, an annular shape to reduce a contact area in which the ohmic-electrode layer 205 and the second conductivity-type semiconductor layer 204 is reduced. Since the insulating region 206 is disposed on the outer edges of the chip, carriers may not be injected into the region having a reduced level of crystallinity due to dicing, thus reducing non-radiative recombination. The ohmic-electrode layer 205 may be made of a light-transmissive material, and in the present example, it is preferably made of a metal having high reflectivity, so as to reflect light emitted from the active layer 203, and in consideration of this function, the ohmic-electrode layer 205 may be formed to include a material such as silver (Ag), nickel (Ni), aluminum (Al), rhodium (Rh), palladium (Pd), iridium (Ir), ruthenium (Ru), magnesium (Mg), zinc (Zn), platinum (Pt), gold (Au), or the like.

The conductive substrate 207 may be connected to external power to apply an electrical signal to the second conductivity-type semiconductor layer 204. Also, the conductive substrate 207 supports the light emitting structure during a process such as a laser lift-off process, or the like, for removing a substrate used for a semiconductor growth, and may be made of a material including any one of gold (Au), nickel (Ni), aluminum (Al), copper (Cu), tungsten (W), silicon (Si), selenium (Se), and GaAs, e.g., a material doped with aluminum (Al) on a silicon (Si) substrate. In this case, the conductive substrate 207 may be disposed on the ohmic-electrode layer 205 through a process such as plating, sputtering, deposition, or the like, and alternatively, a previously fabricated conductive substrate 207 may be joined to the ohmic-electrode layer 207 by the medium of a conductive adhesive layer, or the like.

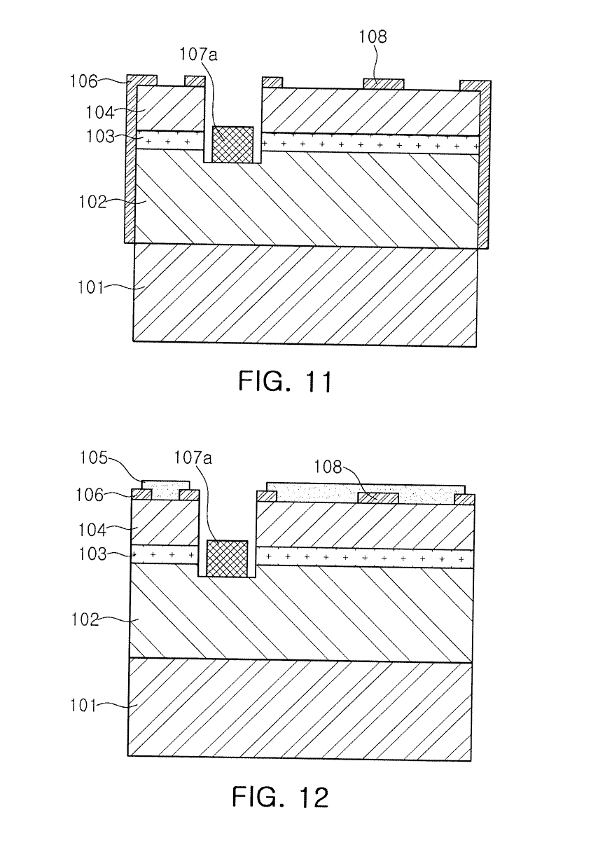

A method for fabricating a semiconductor light emitting device having the foregoing structure(s) or a structure obtained by modifying the foregoing structure(s) will now be described. FIGS. 8 through 12 are cross-sectional views schematically showing a sequential process of a method for fabricating a semiconductor light emitting device according to an example of the present application. Here, the fabrication method is described based on the device of FIG. 4 but it may also be used for fabricating a different example.

First, as shown in FIG. 8, a light emitting structure, namely, including the first conductivity-type semiconductor layer 102, the active layer 103, and the second conductivity-type semiconductor layer 104, on the substrate 101. As mentioned above, the first conductivity-type semiconductor layer 102, the active layer 103, and the second conductivity-type semiconductor layer 104 may be formed through a process such as MOCVD, MBE, HVPE, or the like. Also, although not shown, a buffer layer having various structures (a crystal structure, an amorphous structure, and the like) for enhancing crystallinity may be disposed on the substrate before the first conductivity-type semiconductor layer 102 is formed.

Next, as shown in FIG. 9, portions of the light emitting structure, specifically, portions of at least the active layer 103 and the second conductivity-type semiconductor layer 104 are removed to form the mesa etched region M, and accordingly, a portion of the first conductivity-type semiconductor layer 102 is exposed. This process may be performed by applying a dry etching process such as inductively coupled plasma-reactive ion etching (ICP-RIE), or the like, after a mask is disposed on regions other than the mesa etched region M, or alternately, a wet etching may also be used. Also, although not shown, a dicing process may be performed to sever the light emitting structure into individual chip units before or after the mesa etched region M is formed or simultaneously with the formation of the mesa etched region M. When the mesa etching process or dicing process is executed as described above, an outer region among the remaining regions may be damaged due to the etching. Meanwhile, the mesa etching process of FIG. 9 may not be excluded when the device having the structure illustrated in FIG. 7 is fabricated. The device having the structure illustrated in FIG. 7 may be fabricated by forming the light emitting structure, the insulating region, and the ohmic-electrode layer, forming the conductive substrate, then, removing the substrate 101.

In order to reduce a degradation of luminance efficiency resulting from damage to the outer region, as shown in FIG. 10, the insulating region 106 is formed along the outer edges of the upper surface of the second conductivity-type semiconductor layer 104. The insulating region 106 may have an annular shape in order to entirely insulate the edges of the light emitting structure. As mentioned above, the insulating region 106 may be made of a silicon oxide, a silicon nitride, an aluminum oxide, or the like, and may be formed through an appropriate process such as deposition, sputtering, or the like, using a mask. One of the insulating regions 106 may be formed to surround the mesa etched region M and the other may be formed along the entire outer edges of the chip, namely, the outer edges of the upper surface of the second conductivity-type semiconductor layer 104 to surround all of the ohmic-electrode layer 105 and the first and second electrodes 107a and 107b to be formed thereafter.

Meanwhile, the insulating region 106 may not be disposed only on the upper surface of the second conductivity-type semiconductor layer 104; namely, as shown in FIG. 11, the insulating region 106 may also be formed to extend to cover a lateral surface of the light emitting structure. Also, the current spreading region 108 may be disposed on the other region of the upper surface of the second conductivity-type semiconductor layer 104, and here, the current spreading region 108 is formed in a position corresponding to the second electrode to be formed thereafter in order to spread a current in the lateral direction. The current spreading region 108 may be made of the same material as that of the insulating region 106 and may be simultaneously formed when the insulating region 106 is formed. In this manner, the simultaneous formation of the current spreading region 108 and the insulating region 106 can increase process convenience.

Then, as shown in FIG. 12, the ohmic-electrode layer 105 is disposed on the second conductivity-type semiconductor layer 104, and here, the ohmic-electrode layer 105 may be formed to cover at least a portion of the insulating region 106. The ohmic-electrode layer 105 may be made of a transparent conductive oxide or a metal such as silver (Ag), aluminum (Al), or the like, and may be formed through a process such as deposition, sputtering, or the like. As mentioned above, the ohmic-electrode layer 105 may not be in contact with the second conductivity-type semiconductor layer 104 in the edge region of the light emitting structure having damaged crystallinity or in the vicinity of the mesa etched region. After the ohmic-electrode layer 105 is formed, the first and second electrodes 107a and 107b may be formed to obtain the light emitting device having the configuration as illustrated in FIG. 4.

As set forth above, according to examples of the application, the semiconductor light emitting device, from which a quantity of light emitted to the outside is increased, can be obtained, and in addition, a method for effectively fabricating such a semiconductor light emitting device can also be obtained. However, the effect that can be obtained from the present application is not limited thereto and any object and effect that can be recognized from the technical solutions and examples described above may be included although not clarified.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

1. A semiconductor light emitting device comprising:
a first conductivity-type semiconductor layer;
an active layer disposed on the first conductivity-type semiconductor layer;
a second conductivity-type semiconductor layer disposed on the active layer;
an insulating region disposed along outer edges of an upper surface of the second conductivity-type semiconductor layer, wherein the insulating region is divided into a plurality of separated insulating regions;
an ohmic-electrode layer disposed on the second conductivity-type semiconductor layer above the plurality of separated insulating regions;
a first electrode disposed on a portion of the first conductivity-type semiconductor layer; and
a second electrode disposed on a portion of the ohmic-electrode layer.

2. The semiconductor light emitting device of claim 1, wherein the insulating region includes an annular shape on the outer edges of the upper surface of the second conductivity-type semiconductor layer.

3. The semiconductor light emitting device of claim 2, wherein a distance from an outermost edge of the second conductivity-type semiconductor layer to an inner circumferential surface of the insulating region including the annular shape ranges from 5 μm to 45 μm.

4. The semiconductor light emitting device of claim 1, further comprising:
a mesa etched region extending through portions of the active layer and the second conductivity-type semiconductor layer such that a portion of the first conductivity-type semiconductor layer is exposed, wherein
the first electrode is formed in the mesa etched region.

5. The semiconductor light emitting device of claim 4, wherein one of the plurality of separated insulating regions surrounds the mesa etched region when viewed from above.

6. The semiconductor light emitting device of claim 1, wherein the insulating region surrounds the ohmic-electrode layer and the first and second electrodes when viewed from above.

7. The semiconductor light emitting device of claim 1, further comprising:
a current spreading region made of an electrical insulation material and disposed in a position corresponding to the second electrode below the second electrode.

8. The semiconductor light emitting device of claim 7, wherein the current spreading region has a shape the same as that of the second electrode.

9. The semiconductor light emitting device of claim 7, wherein the current spreading region is made of a material the same as that of the insulating region.

10. The semiconductor light emitting device of claim 1, wherein the insulating region has an inner circumferential surface having depressions and protrusions formed therein.

11. The semiconductor light emitting device of claim 1, wherein the ohmic-electrode layer covers at least a portion of the insulating region.

12. The semiconductor light emitting device of claim 1, wherein the ohmic-electrode layer is made of a light-transmissive material.

13. The semiconductor light emitting device of claim 1, wherein the ohmic-electrode layer is made of a light-reflective material.

14. A semiconductor light emitting device comprising:
a first conductivity-type semiconductor layer;
an active layer disposed on the first conductivity-type semiconductor layer;
a second conductivity-type semiconductor layer disposed on the active layer;
an insulating region formed along outer edges of an upper surface of the second conductivity-type semiconductor layer, wherein the insulating region is divided into a plurality of separated insulating regions;
an ohmic-electrode layer disposed on the second conductivity-type semiconductor layer above the plurality of separated insulating regions;
a first electrode disposed on a portion of the first conductivity-type semiconductor layer; and
a trench extending through the second conductivity-type semiconductor layer, the active layer and a portion of the first conductivity-type semiconductor layer.

15. The semiconductor light emitting device of claim 14, wherein the insulating region includes an annular shape on the outer edges of the upper surface of the second conductivity-type semiconductor layer.

16. The semiconductor light emitting device of claim 14, wherein the ohmic-electrode layer is disposed to cover at least a portion of the insulating region.

17. The semiconductor light emitting device of claim 14, wherein the ohmic-electrode layer is made of a light-transmissive material.

18. The semiconductor light emitting device of claim 14, wherein the ohmic-electrode layer is made of a light-reflective material.

19. A semiconductor light emitting device comprising:
a first conductivity-type semiconductor layer;
an active layer disposed on the first conductivity-type semiconductor layer;
a second conductivity-type semiconductor layer disposed on the active layer;
an insulating region disposed along outer edges of an upper surface of the second conductivity-type semiconductor layer, wherein the insulating region is divided into a plurality of separated insulating regions;
an ohmic-electrode layer disposed on the second conductivity-type semiconductor layer above the plurality of separated insulating regions;
a conductive substrate disposed on the ohmic-electrode layer;
a first electrode disposed on a portion of the first conductivity-type semiconductor layer; and
a second electrode disposed on a portion of the ohmic-electrode layer.

20. The semiconductor light emitting device of claim 19, wherein the conductive substrate includes a material having any one of gold (Au), nickel (Ni), aluminum (Al), copper (Cu), tungsten (W), silicon (Si), selenium (Se), and GaAs.
